(19) United States
(12) Patent Application Publication
(10) Pub. No.: US 2008/0087996 A1
(43) Pub. Date: Apr. 17, 2008

(54) SEMICONDUCTOR DEVICE AND MANUFACTURING METHOD OF THE SAME

(76) Inventors: Yoshinori MIYAKI, Tokyo (JP); Hiromichi Suzuki, Tokyo (JP)

Correspondence Address: MILES & STOCKBRIDGE PC, 1751 PINNACLE DRIVE, SUITE 500, MCLEAN, VA, 22102-3833, US

(21) Appl. No.: 11/858,880

(22) Filed: Sep. 20, 2007

(30) Foreign Application Priority Data
Oct. 13, 2006 (JP) 2006-279759

(51) Int. Cl. H01L 23/495; H01L 21/00

(52) U.S. Cl. 257/677; 438/123; 257/E23.031

(57) ABSTRACT

An object of the invention is to improve a reliability of a semiconductor device. The semiconductor device comprises a semiconductor chip, a tab having an outside dimension smaller than that of the semiconductor chip, a plurality of wires, a plurality of inner leads which extend around the semiconductor chip and have, on a wire bonding portion to which a wire is bonded, a Pd plated layer, a resin sealant, and a plurality of outer leads having a Pd plated layer formed on the surface thereof. The inner leads, outer leads and tab are each made of a Cu alloy. Inside the resin sealant, a strike plated layer having on the surface thereof a pure Cu layer has been formed to expose it from a region of each of the inner leads other than the wire bonding portion. The strike plated layer is therefore bonded to the resin sealant, making it possible to improve the adhesion between the resin and the lead, thereby improving the reliability of the semiconductor device.

### CROSS-REFERENCE TO RELATED APPLICATIONS

The disclosure of Japanese Patent Application No. 2006-279759 filed on Oct. 13, 2006 including the specification, drawings and abstract is incorporated herein by reference in its entirety.

### BACKGROUND OF THE INVENTION

The present invention relates to a semiconductor device and a manufacturing technology thereof, particularly to a technology effective when applied to the manufacture of a lead-free semiconductor device having a small tab structure.

There is disclosed a technology for manufacturing a lead flame plate comprising covering, with a thin Al layer, thin Ni layer and thin Pd layer, both sides of a substrate made of an Fe—Ni-based alloy containing from 30 to 50 wt. % of Ni and heating the resulting multilayer plate to from 400 to 800° C. to diffuse both Al and Ni to prepare a thin NiAl layer and/or a thin Ni₃Al layer (refer to, for example, Japanese Patent Laid-Open No. Hei 10(1998)-18056).

There is disclosed another technology of forming, in a semiconductor device, a metal layer containing a palladium layer at a portion to which a conductive connection member is to be connected and disposing, outside a portion to be sealed with a resin, an alloy layer having a higher melting point than that of a tin-lead eutectic solder and containing no lead as a main metal component (for example, refer to Japanese Patent Laid-Open No. 2001-230360).

### SUMMARY OF THE INVENTION

A semiconductor package (semiconductor device) equipped with a semiconductor chip is fabricated by successively carrying out die bonding, wire bonding, resin sealing and the like and then forming, as external plating in a subsequent external plating step, a tin (Sn)-lead (Pb) based solder layer on surface portions of a lead (which will hereinafter be called “outer lead”) including a contact portion thereof with a circuit substrate which are not sealed with a resin in order to mount on a printed wiring assembly or the substrate.

Since there is an eager demand for overcoming environmental problems, a reduction in a lead content of typical electronic parts such as semiconductor devices or mounting substrates to an adequate level is requested as an environmental countermeasure.

When a lead-free replacement for an Sn—Pb eutectic solder is used for external plating, a proper Sn-containing alloy is selected depending on its using purpose. In particular, an alloy excellent in bonding strength with a mounting substrate and thermal fatigue property is desired in car parts, fastest growing portable electronic appliances and highly reliable parts. Sn—Ag based alloys are known as an Sn-containing alloy excellent in bonding strength and thermal fatigue property and usable when high reliability is emphasized. An Sn—Pb eutectic solder typically has a melting point of 183° C., while most of Sn—Ag based alloys have a melting point of 200° C. or greater, higher than that of the Sn—Pb eutectic solder.

Under the present state, therefore, the reflow temperature when a semiconductor device is mounted using a lead-free replacement for an Sn—Pb eutectic solder is inevitably high. An increase in the reflow temperature causes a relative increase in the expansion/shrinkage amount (thermal stress, resin stress) of a resin. During mounting, a semiconductor chip, a portion of a lead frame (inner lead and chip supporting portion) and a wire are covered with the resin. A lead frame made of an alloy has only lower adhesion with the resin than that between the semiconductor chip and resin. An increase in expansion/shrinkage amount of the resin therefore tends to cause such reflow cracks as to separate a particularly wide interface between a chip support and the resin in the lead frame covered with the resin, due to expansion/shrinkage. Employment of a small tab structure by making the area of a chip support smaller than that of a semiconductor chip as described in the latter Patent Document enables widening of an adhesion area between the resin and the semiconductor chip, thereby avoiding reflow cracks.

A resin stress is also applied to a wire bonding portion. As plating for the wire bonding portion of an inner lead, relatively cheap silver plating tends to be used. An increase in the resin stress due to a rise in reflow temperature however leads to a wire bonding failure (wire disconnection) because a bonding strength between silver plating and wire (such as Au wire) is not sufficient for the wire bonding portion to endure an increased resin stress.

As a countermeasure against the wire bonding failure due to resin stress, a technology using palladium (Pd) plating higher in a bonding strength to a gold (Au) than silver (Ag) plating is known.

For forming a Pd plated layer on a lead frame, a method of forming a Pd plated layer on the entire surface of the lead frame and a method of forming a Pd plated layer only on the wire bonding portion of an inner lead are known. The former method is described in the Japanese Patent Laid-Open No. Hei 10(1998)-18056, while the latter method is described in the Japanese Patent Laid-Open No. 2001-230360.

When a lead frame using, as a raw material, a Cu-based metal (copper alloy) having a lower resistance than that of an Fe—Ni-based alloy is employed in order to raise the speed of a semiconductor device, the lead frame covered entirely with Pd plating as in the Japanese Patent Laid-Open No. Hei 10(1998)-18056 may cause peeling at an interface between the resin and Pd at the time of high temperature treatment such as reflow because Pd has, by its nature, higher hardness than Cu so that it has lower adhesion with the resin than Cu. In this case, a load is applied to a portion where a wire and plate are bonded and a wire bonding failure caused by peeling of plate may pose a problem. Since palladium plating needs more material cost than silver plating, Pd plating all over the surface of the lead frame inevitably raises a manufacturing cost of a semiconductor device.

When a palladium (Pd) plated layer is formed only on the wire bonding portion of an inner lead as described in the Japanese Patent Laid-Open No. 2001-230360, that is, partial plating is performed, on the other hand, a contact region between a sealant resin and an inner lead made of a Cu-based metal can be improved compared with the formation of a palladium plated layer all over the surface of the lead frame as in the Japanese Patent Laid-Open No. Hei 10(1998)-18056, thereby making it possible to suppress the above-described interfacial peeling between the resin and lead frame. Even if partial plating technology is applied, however, the problem of interfacial peeling cannot be prevented completely. The reason for it will next be explained based on the adhesion between a resin and an inner lead made of a Cu-based alloy. A lead frame made of a Cu-based alloy is formed by incorporating various alloy elements in pure Cu. A portion of the lead frame not covered with plating will be an oxide film by the oxidation of the alloy elements exposed from the surface. When a sufficient amount of Cu is supplied during bonding of Cu and oxygen, Cu₂O which has high Cu density and is a strong oxide is formed. In addition, Cu₂O is an oxide film so that it has high adhesion with a resin and the oxide film itself is strong.

When an insufficient amount of Cu is supplied and an amount of oxygen is large, on the other hand, CuO which is a brittle oxide film is formed. This means that in a region of an inner lead where no palladium plated layer has been formed, a brittle CuO film is formed. As a result, the resin and inner lead separate from each other and water penetrates between them. Mounting of a semiconductor device with water absorbed therein causes a popcorn phenomenon and poses a problem of wire breakage or leakage failure.

In view of the above-described problems, it is necessary to improve the adhesion between a resin and a lead frame in a semiconductor device required to have high reliability.

QFP (Quad Flat Package) has a longer inner lead portion in a sealant than QFN (Quad Flat Non-leaded package), meaning that it has a greater contact area between the inner lead and resin in the sealant. Particularly in a QFP type semiconductor device, peeling tends to occur between the inner lead and resin.

An object of the present invention is to provide a technology capable of improving the reliability of a semiconductor device.

Another object of the present invention is to provide a technology capable of reducing the cost of a semiconductor device.

The above-described and the other objects and novel features of the present invention will be apparent from the description herein and accompanying drawings.

Outline of typical inventions, of the inventions disclosed by the present application, will hereinafter be described briefly.

In one aspect of the present invention, there is thus provided a semiconductor device comprising a chip mounting portion, a plurality of leads arranged around the chip mounting portion, a semiconductor chip mounted over the chip mounting portion, a plurality of wires for electrically connecting a plurality of surface electrodes of the semiconductor chip to wire bonding portions of respective first portions of the leads, and a resin sealant for sealing, with a resin, the semiconductor chip, the first portions and the wires, wherein a pure copper layer is formed over the surface of the leads, a palladium plated layer is formed over the uppermost surface of the wire bonding portions, the wires are electrically connected to the wire bonding portions via the palladium plated layer, and a portion of the resin sealant is bonded to the pure copper layer.

In a second aspect of the present invention, there is also provided a manufacturing method of a semiconductor device, which comprises connecting, via a wire, a semiconductor chip and a palladium plated layer formed over the wire bonding portion of a lead; and forming a resin sealant by sealing, with a resin, a lead frame in which a palladium plated layer has been formed over a portion of each of plurality of leads and wire bonding portion and a plated layer having on the surface thereof a pure copper layer has been formed to expose it from a region other than the portion of each of plurality of leads and wire bonding portion. A first region of each of the plurality of leads from which a plated layer is exposed is bonded to a resin sealant inside the resin sealant, while a second region exposed from the resin sealant has a palladium plated layer formed on the surface thereof.

Advantages available from typical inventions, of the inventions disclosed by the present application, will next be described briefly.

A plated layer having on the surface thereof a pure copper layer is exposed from a region of each of the plurality of leads other than the wire bonding portion and this plated layer is bonded to the resin sealant so that adhesion between the resin and lead can be improved, whereby the resulting semiconductor device can have improved reliability.

Moreover, since the palladium plated layer is formed on the wire bonding portion of the lead and over a portion of the lead exposed from the resin sealant, a using amount of palladium (Pd) can be made smaller than an amount of palladium used for the formation of a palladium plated layer all over the lead frame, whereby the resulting semiconductor device can be manufactured at a lower cost.

### BRIEF DESCRIPTION OF THE DRAWINGS

FIG. 1 is a cross-sectional view illustrating the structure of a QFP which is one example of a semiconductor device according to Embodiment 1 of the present invention;

FIG. 2 includes a cross-sectional view and partial plan view illustrating one example of patterning in the preparation of a lead frame to be used for fabrication of the QFP illustrated in FIG. 1;

FIG. 3 includes a cross-sectional view and plan view illustrating one example of the formation of lead frame strips in the preparation of the lead frame to be used for the fabrication of the QFP illustrated in FIG. 1;

FIG. 4 includes a cross-sectional view and partial plan view illustrating one example of the formation of a Cu strike plated layer in the preparation of the lead frame to be used for the fabrication of the QFP illustrated in FIG. 1;

FIG. 5 includes a cross-sectional view and partial plan view illustrating one example of the formation of a Pd plated layer in the preparation of the lead frame to be used for the fabrication of the QFP illustrated in FIG. 1;

FIG. 6 is a partial plan view illustrating one example of a masked back surface of the lead flame before Pd plating in the preparation of the lead frame illustrated in FIG. 5;

FIG. 7 is a partial plan view illustrating one example of the plated back surface of the lead frame after the formation of a Pd-plated layer in the preparation of the lead frame illustrated in FIG. 5;

FIG. 8 includes a plan view and partial plan view illustrating one example of the steps until wire bonding completion in the fabrication of the QFP illustrated in FIG. 1;

FIG. 9 includes a plan view, partial plan view and side surface view illustrating one example of the steps after wire bonding in the fabrication of the QFP illustrated in FIG. 1;

FIG. 10 is a cross-sectional view specifically illustrating one example of the steps until completion of the wire bonding in the fabrication of the QFP illustrated in FIG. 1;

FIG. 11 is a cross-sectional view specifically illustrating one example of the steps after wire bonding in the fabrication of the QFP illustrated in FIG. 1;

FIG. 12 is a partial cross-sectional view illustrating the structure of a QFP which is a modification example of the semiconductor device of Embodiment 1;

FIG. 13 includes a partial cross-sectional view and cross-sectional view illustrating one example of the structure of an oxide film formed on a Cu strike plated layer of the QFP illustrated in FIG. 1;

FIG. 14 is a partial cross-sectional view and cross-sectional view illustrating the structure of an oxide film on an inner lead of a QFP according to Comparative Example;

FIG. 15 is a cross-sectional view illustrating the structure of a QFP as one example of a semiconductor device according to Embodiment 2 of the present invention;

FIG. 16 includes a cross-sectional view and partial plan view illustrating one example of the formation of a Pd plated layer in the preparation of a lead frame to be used for the fabrication of the QFP illustrated in FIG. 15;

FIG. 17 includes a partial plan view illustrating one example of a masked back surface of the frame before formation of the Pd-plated layer in the preparation of the lead frame shown in FIG. 16;

FIG. 18 is a partial plan view illustrating one example of the plated back surface of the frame after formation of the Pd plated layer in the preparation of the lead frame shown in FIG. 16;

FIG. 19 includes a plan view and partial plan view illustrating one example of the steps until completion of die bonding in the fabrication of the QFP shown in FIG. 15;

FIG. 20 is a partial plan view illustrating one example of the steps from wire bonding to the completion of resin molding in the fabrication of the QFP shown in FIG. 15;

FIG. 21 includes a plan view, partial plan view and side surface view illustrating one example of the steps from the formation of a plated layer on the outer lead until the completion of cutting and bending of the lead in the fabrication of the QFP shown in FIG. 15;

FIG. 22 is a cross-sectional view illustrating the structure of a QFN which is one example of a semiconductor device according to Embodiment 3 of the present invention;

FIG. 23 illustrates the structure of the back surface of the QFN illustrated in FIG. 22; and

FIG. 24 is a partially enlarged cross-sectional view illustrating the structure of portion A illustrated in FIG. 22.

### DETAILED DESCRIPTION OF THE INVENTION

In the below-described embodiments, a description will be made after divided in plural sections or in plural embodiments if necessary for convenience's sake. These plural sections or embodiments are not independent each other, but in a relation such that one is a modification example, details or complementary description of a part or whole of the other one unless otherwise specifically indicated.

In the below-described embodiments, when a reference is made to the number of elements (including the number, value, amount and range), the number is not limited to a specific number but can be greater than or less than the specific number unless otherwise specifically indicated or principally apparent that the number is limited to the specific number.

Moreover in the below-described embodiments, it is needless to say that the constituting elements (including element steps) are not always essential unless otherwise specifically indicated or principally apparent that they are essential.

Similarly, in the below-described embodiments, when a reference is made to the shape or positional relationship of the constituting elements, that substantially analogous or similar to it is also embraced unless otherwise specifically indicated or principally apparent that it is not. This also applies to the above-described value and range.

The embodiments of the present invention will next be described in detail based on accompanying drawings. In all the drawings for describing the embodiments, like members of a function will be identified by like reference numerals and overlapping descriptions will be omitted.

### EMBODIMENT 1

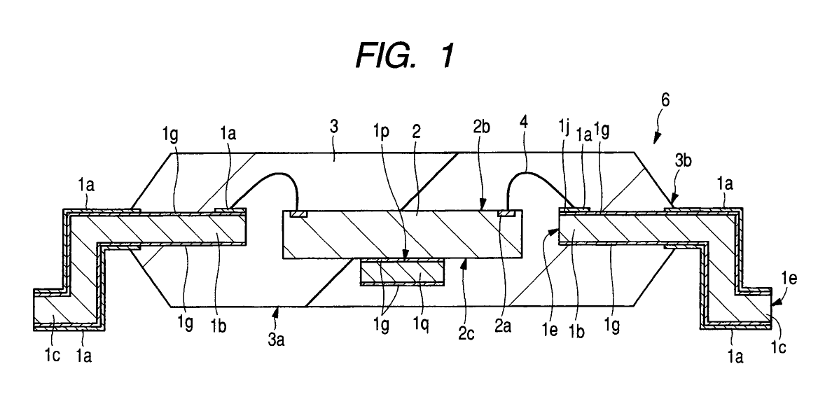

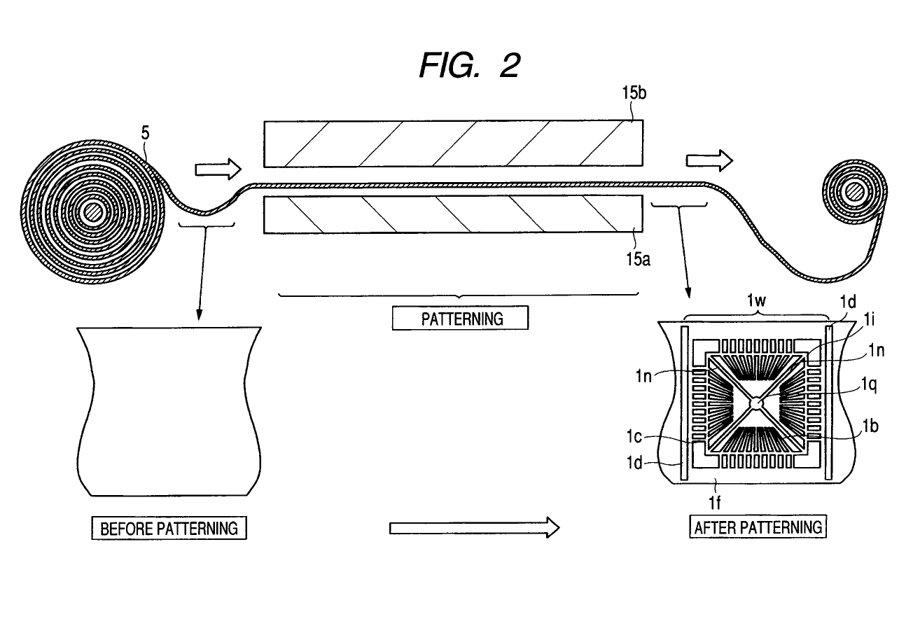

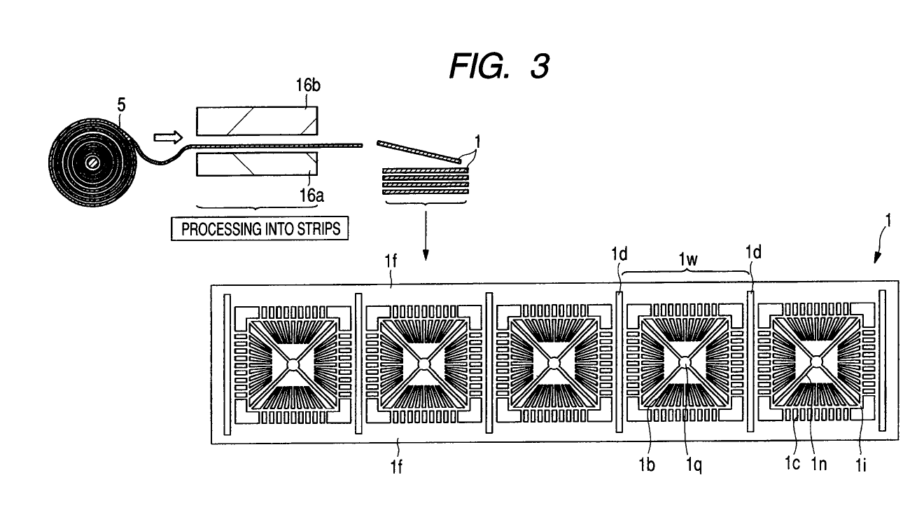

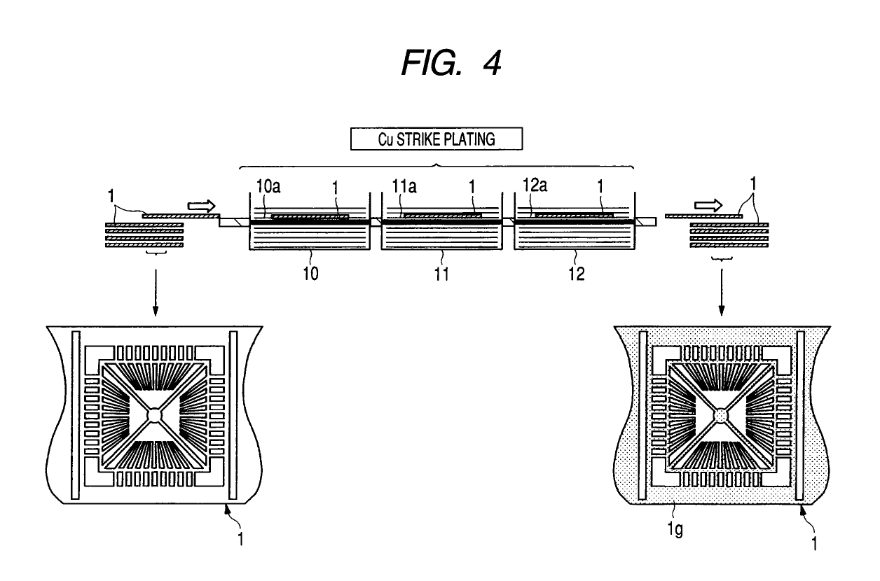

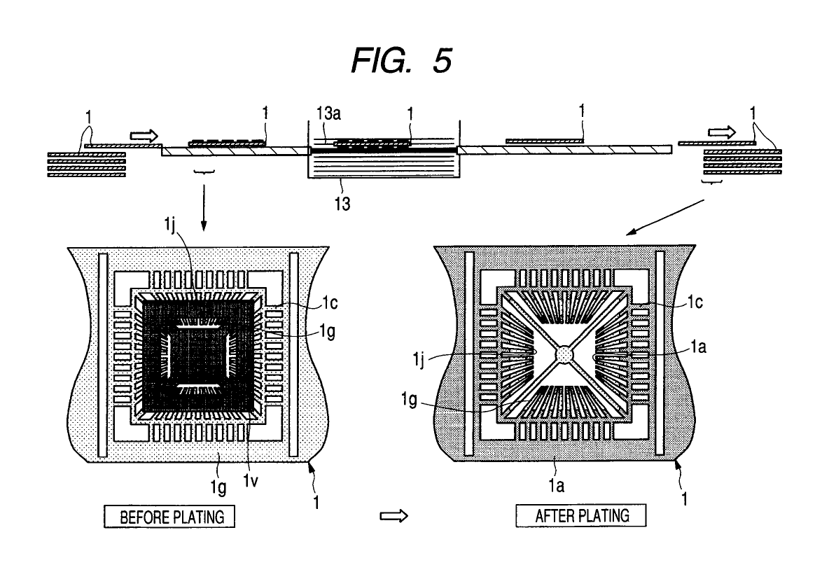

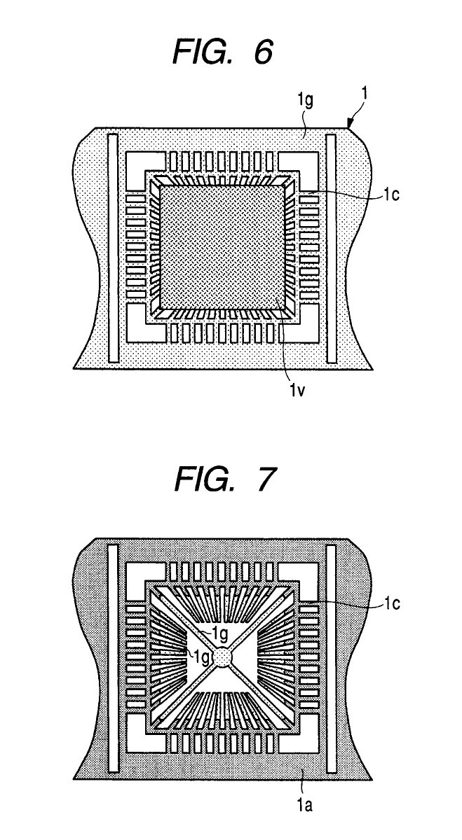

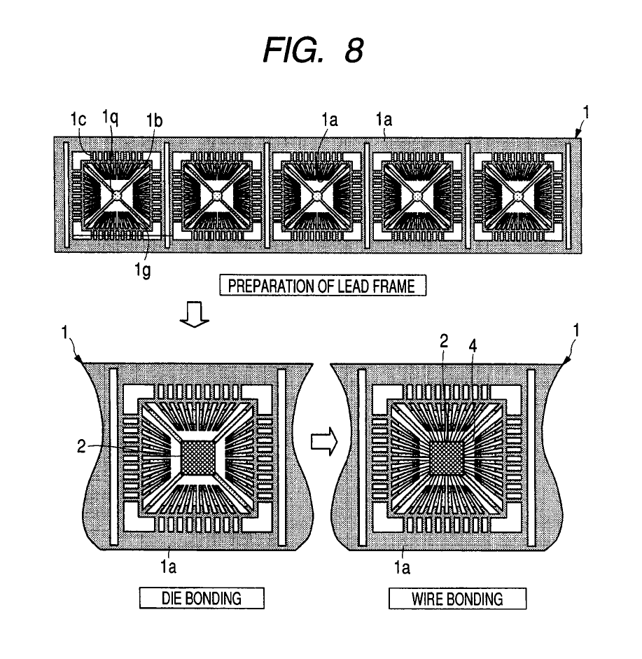

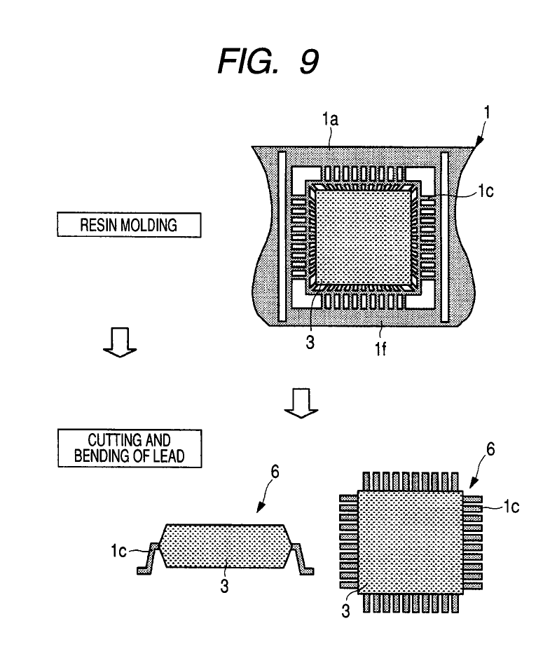

FIG. 1 is a cross-sectional view illustrating the structure of a QFP which is one example of a semiconductor device according to Embodiment 1 of the present invention; FIG. 2 includes a cross-sectional view and partial plan view illustrating one example of patterning in the preparation of a lead frame to be used for fabrication of the QFP illustrated in FIG. 1; FIG. 3 includes a cross-sectional view and plan view illustrating one example of the formation of lead frame strips in the preparation of the lead frame to be used for the fabrication of the QFP illustrated in FIG. 1; FIG. 4 includes a cross-sectional view and partial plan view illustrating one example of the formation of a Cu strike plated layer in the preparation of the lead frame to be used for the fabrication of the QFP illustrated in FIG. 1; FIG. 5 includes a cross-sectional view and partial plan view illustrating one example of the formation of a Pd plated layer in the preparation of the lead frame to be used for the fabrication of the QFP illustrated in FIG. 1; FIG. 6 is a partial plan view illustrating one example of a masked back surface of the lead flame before Pd plating in the preparation of the lead frame illustrated in FIG. 5; FIG. 7 is a partial plan view illustrating one example of the plated back surface of the lead frame after the formation of a Pd-plated layer in the preparation of the lead frame illustrated in FIG. 5; FIG. 8 includes a plan view and partial plan view illustrating one example of the steps until wire bonding completion in the fabrication of the QFP illustrated in FIG. 1; and FIG. 9 includes a plan view, partial plan view and side surface view illustrating one example of the steps after wire bonding in the fabrication of the QFP illustrated in FIG. 1.

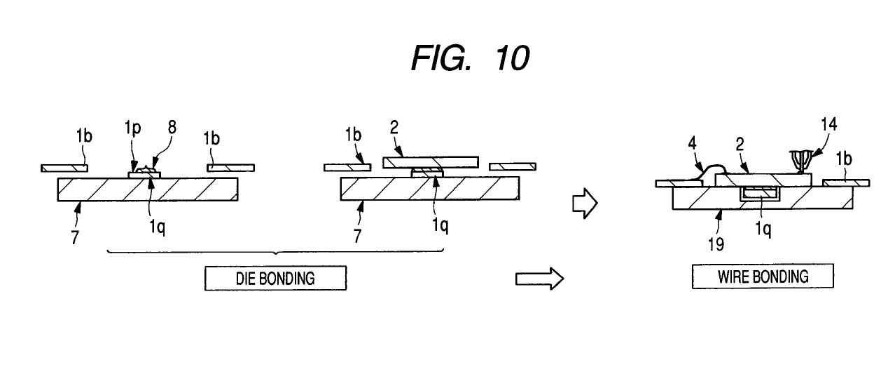

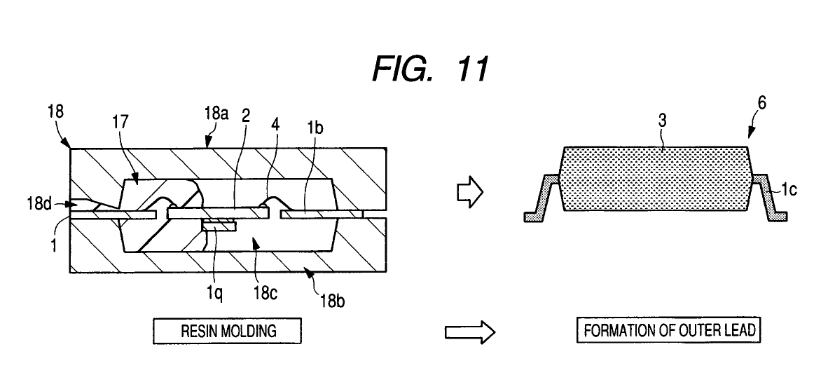

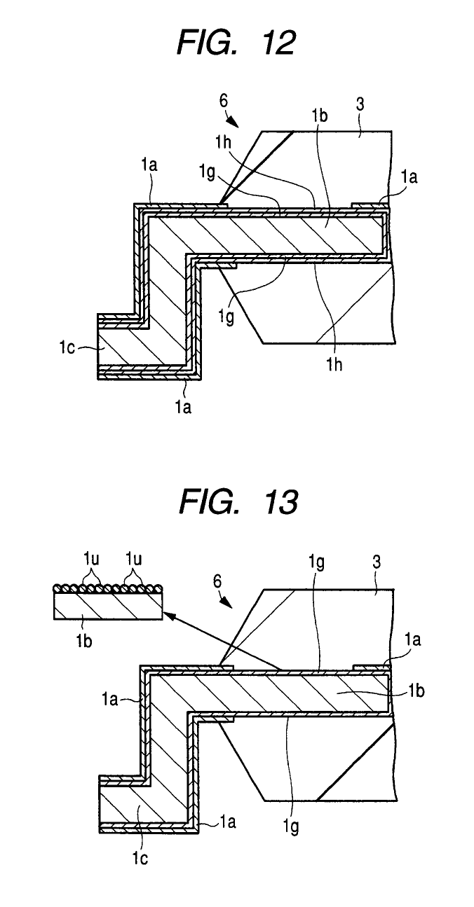

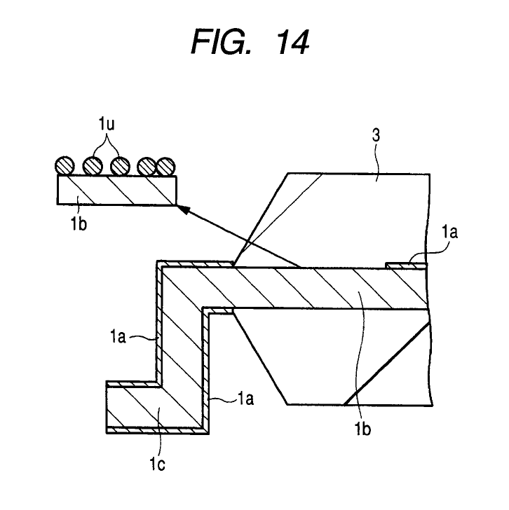

FIG. 10 is a cross-sectional view specifically illustrating one example of the steps, in the fabrication of the QFP illustrated in FIG. 1, until completion of the wire bonding; FIG. 11 is a cross-sectional view specifically illustrating one example of the steps, in the fabrication of the QFP illustrated in FIG. 1, after wire bonding; FIG. 12 is a partial cross-sectional view illustrating the structure of a QFP which is a modification example of the semiconductor device of Embodiment 1; FIG. 13 includes a partial cross-sectional view and cross-sectional view illustrating one example of the structure of an oxide film formed on a Cu strike plated layer of the QFP illustrated in FIG. 1; and FIG. 14 is a partial cross-sectional view and cross-sectional view illustrating the structure of an oxide film on an inner lead of a QFP according to Comparative Example.

The semiconductor device of Embodiment 1 is a resin sealed type obtained by resin molding and at the same time, a surface mount type. As one example of this semiconductor device, a QFP (Quad Flat Package) 6 shown in FIG. 1 will be taken up for description.

The constitution of the QFP 6 will hereinafter be described. It is equipped with: a semiconductor chip 2 having a main surface 2b and a back surface 2c opposite to the main surface 2b, and having a semiconductor integrated circuit mounted on the chip; a tab (chip support, chip mounting portion) 1q having a supporting surface 1p which is to be bonded to the back surface 2c of the semiconductor chip 2 and has an outside dimension smaller than that of the back surface 2c of the semiconductor chip 2; and a plurality of conductive wires 4 electrically connected to a plurality of pads (surface electrodes) 2a of the semiconductor chip 2. Further, it has: a plurality of inner leads (first portions) 1b having, at a wire bonding portion 1j to which a wire 4 is bonded, a palladium (Pd) plated layer 1a; a resin sealant (sealant) 3 for sealing, with a resin, the semiconductor chip 2, tab 1q, plurality of wires 4 and plurality of inner leads 1b; and a plurality of outer leads (second portions) 1c which are connected integrally to the inner leads 1b, exposed from the side portion 3b of the resin sealant 3 and has the palladium plated layer 1a formed on the surface. The inner leads 1b, outer leads 1c and tab 1q are each made of a thin plate material obtained using a copper (Cu) alloy as a raw material.

Inside the resin sealant 3 of the QFP 6, a plated layer (copper plated layer) 1g is formed by strike plating so as to expose a pure copper (Cu) layer 1h (refer to FIG. 12) in a region other the respective wire bonding portions 1j of the plurality of inner leads 1b, whereby a large portion of the inner lead 1b is bonded to the resin sealant 3 via the plated layer 1g as illustrated in FIG. 1.

The semiconductor chip 2 is made of, for example, silicon and the wire is, for example, a gold (Au) wire. As a sealing resin for forming the resin sealant 3, a thermosetting epoxy resin or the like are used for example. The pure copper (Cu) layer 1h formed by strike plating is a multilayer composed of a copper-based metal and it does not contain impurities other than copper (Cu).

The plurality of outer leads 1c protrude from the side portions 3b corresponding to four sides of the resin sealant 3 and are bent in a gull-wing shape.

The QFP 6 according to Embodiment 1 intends to eliminate a lead (Pb) content from the plating applied to the outer leads 1c. The palladium plated layer 1a is therefore formed on the surface of the outer leads 1c as one example of outer lead-free plating. Moreover, the palladium plated layer 1a is also formed on the wire bonding portion 1j of the inner lead 1b near the side end portion of the chip.

Mounting of the QFP 6 using a lead-free solder requires a high reflow temperature so that use of the tab 1q having a greater outside dimension (planar size) than that of the semiconductor chip 2 tends to generate reflow cracks in the resin portion to be bonded to the tab 1q supporting the semiconductor chip 2. Since the QFP 6 of Embodiment 1 employs a small tab structure in which the outside dimension of the supporting surface 1p of the tab 1q is made smaller than that of the back surface 2c of the semiconductor chip 2, the adhesion area between the resin and lead frame 1 can be reduced and generation of reflow cracks can be avoided.

An increase in the reflow temperature raises the expansion/shrinkage amount (thermal stress, resin stress) of the resin, which also raises a resin stress applied to the wire bonding portion 1j. In the QFP 6 according to Embodiment 1, wire bonding failure can be prevented by forming, on the uppermost surface of the wire bonding portion, the palladium plated layer 1a having a higher bonding strength with the wire 4 (gold wire) than a silver plated layer as plating to the wire bonding portion 1j of the inner lead 1b.

In the QFP 6, the plated layer 1g is formed by strike plating in order to expose the pure copper layer 1h (refer to FIG. 12) in a region of each of the inner leads 1b other than the wire bonding portion 1j. Inside the resin sealant 3, the plated layer 1g formed by strike plating is bonded to the resin sealant 3.

The plated layer 1g is made of a copper metal and has the pure copper layer 1h on at least the surface (uppermost layer) thereof and the pure copper layer 1h must be exposed on the inner lead 1b.

In this Embodiment, the inner lead 1b, outer lead 1c and tab 1q each has a copper alloy as a raw material thereof. Examples of the composition of the copper alloy include 0.3Cr-0.25Sn-0.2Zn-balance of Cu, 3.0Ni-0.65Si-0.15Mg-balance of Cu, and (2.1-2.6)Fe-(0.05-0.20)Zn-(0.015-0.15)P-balance of Cu.

When the inner lead 1b is composed of the above-described Cu alloy, an oxide film 1u is formed on the uppermost surface of the inner lead by natural oxidation as illustrated in FIGS. 13 and 14. The amount of copper (Cu) to be supplied is determined and crystal condition of the oxide film 1u formed on the uppermost surface becomes dense or rough, depending on whether orientation of the copper film formed on the surface (layer lying below the oxide film 1u) of the inner lead 1b is strongly stable or not. In other words, since a sufficient amount (large amount) of copper (Cu) is present when the orientation is strongly stable, a large amount of copper is supplied to the oxide film to be formed on the uppermost surface of the inner lead. As a result, a strong CuO₂ layer having dense crystal conditions is formed. The oxide film 1u is an oxide so that it also has an influence on the adhesion with a resin of the resin sealant 3.

When the plated layer 1g has not been formed on the surface of the inner lead 1b by strike plating as shown in Comparative Example illustrated in FIG. 14, the oxide film 1u formed on the surface becomes rough owing to insufficient amount of Cu. It becomes a fragile CuO layer and cannot improve the adhesion with the resin of the resin sealant 3. In the QFP 6 of this Embodiment shown in FIG. 13, on the other hand, the plated layer 1g having the pure copper layer 1h (refer to FIG. 12) has been formed on the surface of the inner lead 1b by strike plating. A sufficient amount of Cu is present so that the oxide film 1u formed on the surface becomes highly dense and becomes a CuO₂ layer which is a strong film, making is possible to improve the adhesion with the resin sealant 3.

In short, inside the resin sealant 3 of the QFP 6 of Embodiment 1, the plated layer 1g having, on the surface thereof, the pure copper layer 1h is formed to expose it in a region of each of the plurality of inner leads 1b other than the wire bonding portion 1j and this plated layer 1g is bonded to the resin sealant 3 so that the adhesion between the resin and the inner lead 1b can be improved.

As a result, the QFP 6 can have improved reliability.

The length of the inner lead 1b in the QFP structure is longer than that in a QFN (Quad Flat Non-leaded package) structure. The reason why the length of the inner lead is shorter in the QFN structure than that in the QFP structure is because one of the object of the QFN structure is to make the mounting area narrower than that of the QFP structure by causing the outer lead 1c to protrude from the back surface (mounting surface) side of the resin sealant 3 without causing the outer lead 1c to protrude from the side surface of the resin sealant 3 as in the QFP structure. In the QFP structure in which the length of the inner lead is longer than that of the QFN structure, it is very important to heighten the adhesion between the resin and inner lead 1b. It is effective in the QFP structure to expose the plated layer 1g having thereon the pure copper layer 1h in a region of the inner lead 1b other than the wire bonding portion 1j.

The palladium plated layer 1a is formed only on the wire bonding portion 1j of the inner lead 1b and outer lead 1c exposed from the resin sealant 3 so that a using amount of palladium (Pd) can be reduced compared with the formation of palladium plating all over the lead frame. In short, partial plating can reduce the using amount of palladium (Pd) compared with palladium plating all over the lead frame. As a result, the production cost of the semiconductor device of the QFP 6 type can be reduced.

Moreover, the palladium (Pd) plated layer 1a formed on the uppermost layer of the outer lead 1c can prevent generation of whiskers which will otherwise occur easily by tin-copper (Sn—Cu) plating or the like.

FIG. 1 illustrates the structure fabricated by cutting after plating so that a palladium plated layer or a pure copper layer by strike plating has not been formed on a cut surface 1e at the end of the outer lead 1c and a cut surface 1e at the end of the inner lead 1c. When plating is applied after the formation of an inner lead pattern, a pure copper layer may be formed at the end of the inner lead 1b by strike plating.

In the QFP 6 shown in FIG. 1, a portion of the palladium plated layer 1a formed on the surface of the outer lead 1c extends even to the inner lead 1b. In other words, a portion of the palladium plated layer 1a is covered with the resin sealant 3. Described specifically, an end portion (a portion) of the palladium plated layer 1a, which has been formed on the surface of the outer lead 1c, on the chip side extends to the surface of the inner lead 1b by which the end portion of the palladium plated layer 1a on the chip side is covered with the resin sealant 3. At the protruding portion of the outer lead 1c from the side portion 3b of the resin sealant 3, exposure of the plated layer 1g formed by strike plating can be prevented. A whisker phenomenon between two adjacent outer leads 1c can therefore be prevented.

In the QFP 6, a nickel (Ni) layer is formed below the palladium plated layer 1a on the wire bonding portion 1j of the inner lead 1b and the outer lead 1c. In other words, the nickel layer is inserted between the plated layer 1g formed by strike plating and the palladium layer and the nickel layer serves as a barrier to prevent diffusion and penetration of copper into the palladium layer.

As a result, deterioration of bondability due to penetration of copper into the palladium layer can be prevented.

In the palladium plated layer 1a, a gold layer is preferably formed on the palladium layer. In this Embodiment 1, gold (Au) with low resistance is used as a material of the wire so that the gold layer formed on the palladium layer can improve the bondability in wire connection. Moreover, it can improve the wettability with a solder in the palladium plated layer 1a of the outer lead 1c.

A description will next be made of the fabrication of the QFP 6 in Embodiment 1.

First, a preparation process of the lead frame 1 to be used for the fabrication of the QFP 6 will next be described.

As illustrated in FIG. 2, a band-like metal material 5 having a copper alloy as a raw material is prepared and is placed between a die 15a and a punch 15b. Patterning of each lead is performed by punching using the die 15a and punch 15b. By this patterning, a package region 1w is formed between a slit 1d and a slit 1d. One package region 1w corresponds to one QFP 6 and a tab 1q is placed near the center of the package region. A suspending lead in for supporting the tab 1q, a plurality of inner leads 1b and outer leads 1c arranged around the tab 1q, a dumber 1i for connecting the leads and the like are formed and the outer lead 1c is connected to a frame portion 1f placed therearound.

Then, strips of a flame are formed as illustrated in FIG. 3.

In this step, punching with the die 16a and punch 16b is performed to form lead frames 1 in the strip form from the band-like metal material 5. For example, one lead frame 1 has five package regions 1w formed therein so that five QFPs 6 can be formed from one lead frame 1.

As illustrated in FIG. 4, a plated layer (copper plated layer) 1g having a pure copper layer is formed on the lead frame 1 by strike plating. Here, the formation of the plated layer 1g composed singly of a pure copper (Cu) layer will be described. First, the lead frame 1 is dipped in a treatment solution 10a in a pretreatment tank 10. The lead frame 1 is then taken out from the tank and then dipped in a pure copper plating solution 11a in a plating tank 11. By this treatment, the pure copper plated layer 1g is formed over the respective surfaces of the inner lead 1b, outer lead 1c and tab 1q, that is, all over the surface of the lead frame 1. The resulting lead frame 1 is taken out and then dipped in a washing solution 12a in a washing tank 12 to wash the lead frame 1.

As a result, the formation of the pure copper plated layer 1g on the lead frame 1 is completed.

Then, a palladium (Pd) plated layer 1a is formed as illustrated in FIG. 5. First, a nickel (Ni) plated layer to be laid below the palladium (Pd) plated layer 1a is formed. As illustrated in “Before plating” of FIG. 5, a mask 1v is attached to a predetermined position. Here, the mask 1v is attached to expose the outer lead 1c and the wire bonding portion 1j of the inner lead 1b in order to form the plated layer on the outer lead 1c and the wire bonding portion 1j of the inner lead 1b.

On the back surface side of the frame, as illustrated in FIG. 6, a mask 1v is attached to expose the outer lead 1c. Under this condition, the lead frame 1 is dipped in a nickel plating tank to form a nickel plated layer on the outer lead 1c and the wire bonding portion 1j of the inner lead 1b.

By dipping the lead frame 1 in a palladium plating solution 13a in a palladium plating tank 13 as illustrated in FIG. 5, the Pd plated layer 1a is formed over the nickel plated layer. In other words, the palladium plated layer 1a is formed, as illustrated in FIG. 5, on the outer lead 1c and the wire bonding portion 1j of the inner lead 1b. The palladium plated layer 1a is also formed on the outer lead 1c on the back surface side of the frame as illustrated in FIG. 7.

The lead frame 1 is then washed, whereby the plating step is completed.

As illustrated in “After plating” of FIG. 5 and in FIG. 7, the lead frame 1 has the palladium plated layer 1a formed on the outer lead 1c, the wire bonding portion 1j of the inner lead 1b, a portion of the inner lead 1b opposite thereto and near the outer lead 1c, and the frame portion 1f. More specifically, the inner lead 1b has a main surface and a back surface opposite to each other and two side surfaces located therebetween. The palladium plated layer 1a is formed only on the end portion on the main surface of the inner lead 1b and at the same time opposite to the semiconductor chip 2. The outer lead 1c has a main surface and a back surface opposite to each other and two side surfaces located therebetween, and the palladium plated layer 1a is formed on the main surface, back surface and two side surfaces of the outer lead 1c.

From a region of the inner lead 1b of the lead frame 1 where no palladium plated layer 1a has been formed, the pure copper plated layer 1g is exposed. Owing to presence of a sufficient amount of copper (Cu), a natural oxide film of Cu₂O is formed on this plated layer 1g.

The fabrication of the QFP 6 to be performed using the lead frame 1 which has finished the plating step will next be described.

As illustrated in “Preparation of lead frame” of FIG. 8, a lead frame 1 made using a copper alloy as a raw material and equipped with a tab 1q having a support surface 1p smaller in the outside dimension than that of a back surface 2c of a semiconductor chip 2 to be mounted, and a plurality of inner leads 1b and outer leads 1c located to extend around the tab 1q is prepared.

In the lead frame 1, a palladium plated layer 1a has been formed on the plurality of outer leads 1c and a wire bonding portion 1j of the inner leads 1b in advance and at the same time, a pure copper plated layer 1g is formed to exposed it from a region other than the outer leads 1c and the wire bonding portion 1j.

Die bonding as illustrated in FIGS. 8 and 10 is then performed. Described specifically, the semiconductor chip 2 is mounted on the supporting surface 1p of the tab 1q. At this time, the tab 1q is placed on a die bonding stage 7, a die bonding material (adhesive, adhesive film) 8 is applied onto the supporting surface 1p of the tab 1q and then, the semiconductor chip 2 is mounted thereon. By this step, the semiconductor chip 2 is mounted on the supporting surface 1p of the tab 1q via the die bonding material 8. Since the plated layer 1g has been formed by strike plating on both surfaces of the tab 1q, which means, also on the supporting surface 1p of the tab 1q, adhesion between the die bonding material 8 and tab 1q can be improved further.

Wire bonding is then carried out as illustrated in FIGS. 8 and 10. Here, as illustrated in FIG. 10, the semiconductor chip 2 and inner lead 1b are brought into contact with the upper surface of a heat stage 19 for heating. While heating, a pad (surface electrode) 2a of the semiconductor chip 2 and the inner lead 1b are electrically connected via a conductive wire 4 by the aid of a capillary 14. On the side of the inner lead 1b, the wire 4 is connected to the palladium plated layer 1a formed on the wire bonding portion 1j of the inner lead 1b.

In the wire bonding step, bonding is performed by bringing the inner lead 1b into contact with the heat stage 19 so that the inner lead 1b is heated to high temperature. As a result, an oxide film 1u (first oxide film) which has been naturally formed by oxidation on the plated layer 1g having a pure copper layer becomes a strong film (second oxide film) by heating. At the same time, the resulting strong oxide film (second oxide film) increases.

Resin molding is then carried out as illustrated in FIGS. 9 and 11. As shown in “Resin molding” of FIG. 11, resin molding is carried out by filling a resin (sealing resin) 17 in a cavity 18c from an inlet 18d while clamping the lead frame 1 between a top force 18a and a bottom force 18b of a mold die 18, whereby the tab 1q, inner leads 1b, semiconductor chip 2 and a plurality of wires 4 are resin-sealed to form a resin sealant 3 as illustrated in “Resin molding” of FIG. 9. The planar shape of the resin sealant 3 of the QFP 6 according to Embodiment 1 is a tetragon, for example, rectangle. The outer lead 1c is protruded from each side (each side surface) of the resin sealant 3.

In the QFP 6 of Embodiment 1, an end portion (a portion), on the side of the chip, of the palladium plated layer 1a which has been formed on the surface of the outer lead 1c and extends to the inner lead 1b is covered with the resin sealant 3 as illustrated in FIG. 1. This means that exposure of the plated layer 1g from a position at which the outer lead 1c is protruded from the side portion 3b of the resin sealant 3 of the QFP 6 is prevented.

During the fabrication of the QFP 6, the palladium plated layer 1a, as well as the plated layer 1g having a pure copper layer thereon, is formed in advance at the stage of the lead frame and this palladium plated layer 1a is formed on the outer lead 1c and a region (portion) extending over the inner lead 1b from the outer lead 1c. When the resin sealant 3 is formed by resin molding, this makes it possible to cover, with the resin sealant 3, even a region extending over the inner lead 1b from the end portion, on the chip side, of the palladium plated layer 1a formed on the surface of the outer lead 1c.

As a result, it is possible to prevent exposure of the plated layer 1g from the protruding site of the outer lead 1c from the side portion 3b of the resin sealant 3 of the QFP 6 and prevent a whisker phenomenon between two adjacent outer leads 1c. In addition, use of palladium (Pd) for both the inner lead 1b and the surface of the outer lead 1c enables simplification of the plating step. Described specifically, compared with the use of different plating materials for the inner lead 1b and the outer lead 1c, respectively, the number of plating times can be reduced by one. Moreover, since the palladium plated layer 1a has been formed also on the surface of the outer lead 1c in advance at the time of preparation of the lead frame so that no plating step is necessary after the formation of the resin sealant 3.

After completion of the resin molding, cutting and bending (formation of outer lead) are carried out as illustrated in FIGS. 9 and 11. By lead cutting, each outer lead 1c is separated from the frame portion 1f of the lead frame 1 of FIG. 9 and at the same time, each outer lead 1c is bent into a gull-wing shape. By this step, the fabrication of the QFP 6 is completed.

In the QFP 6 after completion of the fabrication, the pure copper plated layer 1g and palladium plated layer 1a has been partially formed. At each inner lead 1b, a first region (first region means a region of the inner lead 1b where no palladium plated layer 1a has been formed and from which the plated layer 1g formed by strike plating has been exposed) from which the plated layer 1g is exposed has been bonded to the resin sealant 3 (sealing resin) inside the resin sealant 3. The plated layer 1g has been formed also on the surface (back surface) opposite to the supporting surface 1p of the tab 1q by strike plating so that the back surface of the tab 1q has also been bonded to the resin sealant 3 via the plated layer 1g. This makes it possible to improve the adhesion between the resin and each inner lead 1b or the tab 1q. Moreover, the palladium plated layer 1a has been formed on the surface of a second region (meaning a portion of the outer lead 1c protruding from the resin sealant 3) exposed from the resin sealant 3.

In the preparation of the lead frame 1, patterning of all the portions of the inner lead 1b and outer lead 1c including the end portion of the inner lead 1b may be performed prior to the formation of the plated layer 1g by strike plating; or the plated layer 1g may be formed by strike plating with the end portions of the two adjacent inner leads 1b being connected to each other, followed by patterning of the end portion of the inner lead 1b.

The formation of the palladium plated layer 1a on the wire bonding portion 1j of the inner lead 1b is performed in advance in the stage of the lead frame 1, but the formation of the palladium plated layer 1a on the outer lead 1c may be performed after resin molding in the fabrication of the QFP 6. This means that the formation of the palladium plated layer 1a on the outer lead 1c may be carried out either as prior plating (plating in the stage of the lead frame) or as post plating (plating after resin molding).

By carrying out the formation of the palladium plated layer 1a by the prior plating as in the fabrication of the QFP 6 of Embodiment 1, the palladium plated layer 1a can be formed on both the inner lead 1b and outer lead 1c in one plating step, which enables elimination of the post treatment of the plating and thereby heightening of the through-put of the preparation of the lead frame 1. As a result, the productivity of the QFP 6 can be enhanced.

Owing to the palladium plated layer 1a formed on the wire bonding portion 1j of the inner lead 1b, connection reliability with the wire 4 (gold wire) can be heightened.

Moreover, since the pure copper plated layer 1g is formed on the inner lead 1b and outer lead 1c by strike plating and no tin (Sn) plating is used, generation of a whisker can be prevented.

Accordingly, it is possible to fabricate the QFP 6 which can satisfy the recent request for lead-free plating and has high productivity and reliability.

A modification example of the QFP 6 of Embodiment 1 will next be described.

FIG. 12 illustrates the modification example of Embodiment 1 in which a plated layer 1g has been formed as a multilayer by strike plating. In other words, the plated layer 1g formed by strike plating may have two or more layers composed of a copper-based metal. The uppermost layer exposed from the surface, however, must be a pure copper layer 1h.

By forming the strike plated layer 1g as a multilayer by using a copper-based metal as illustrated in FIG. 12, a thermal stress applied to the wire bonding portion 1j of the inner lead 1b during the fabrication step of the QFP 6 or the like can be relaxed.

### EMBODIMENT 2

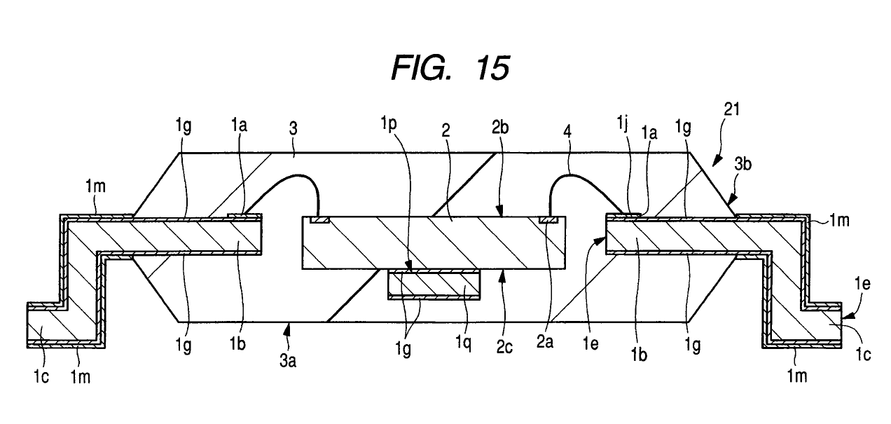

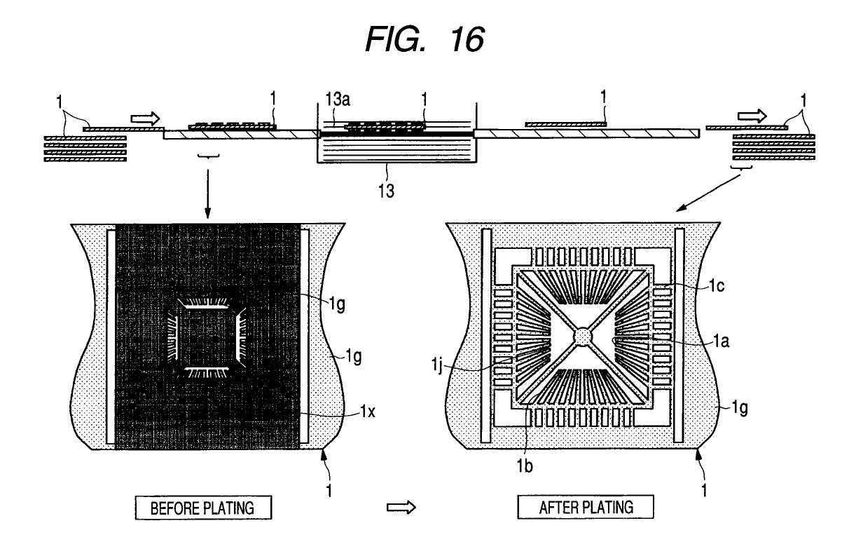

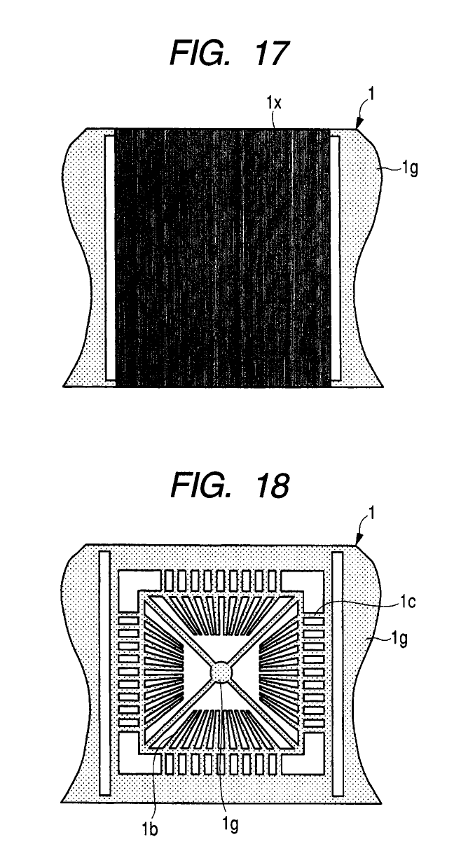

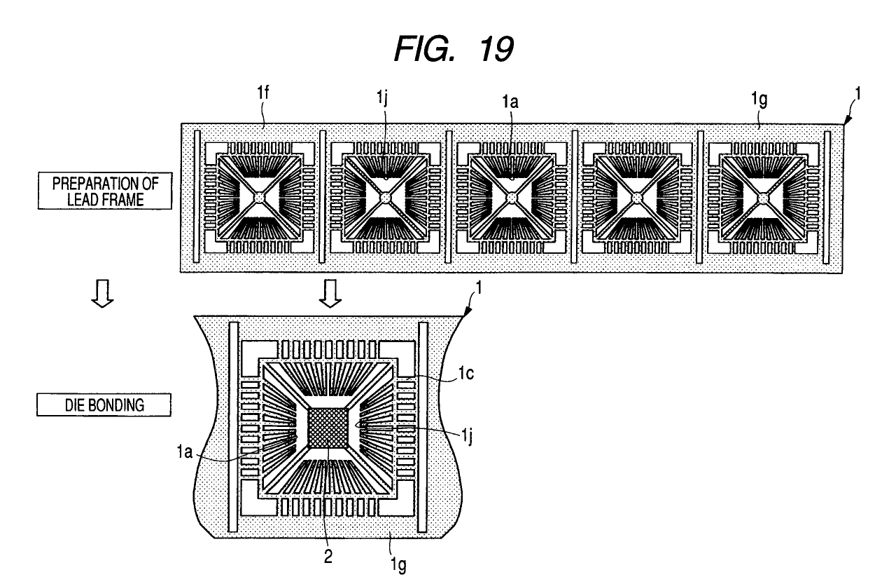

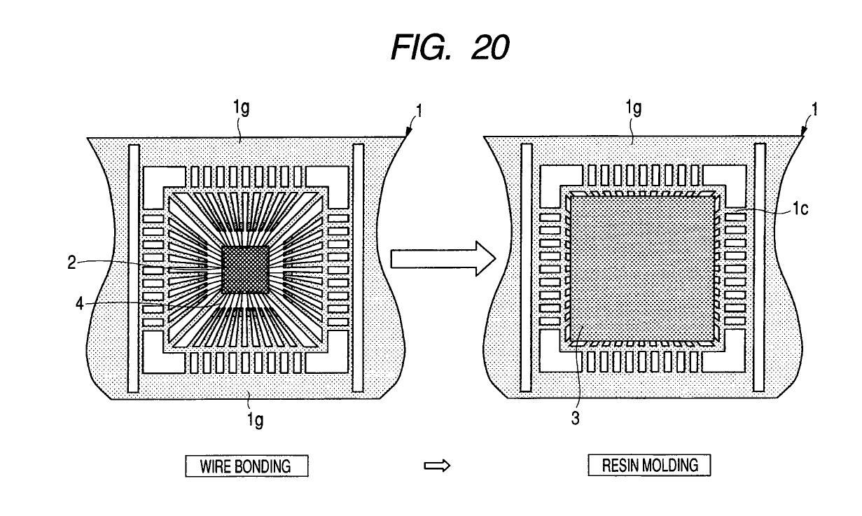

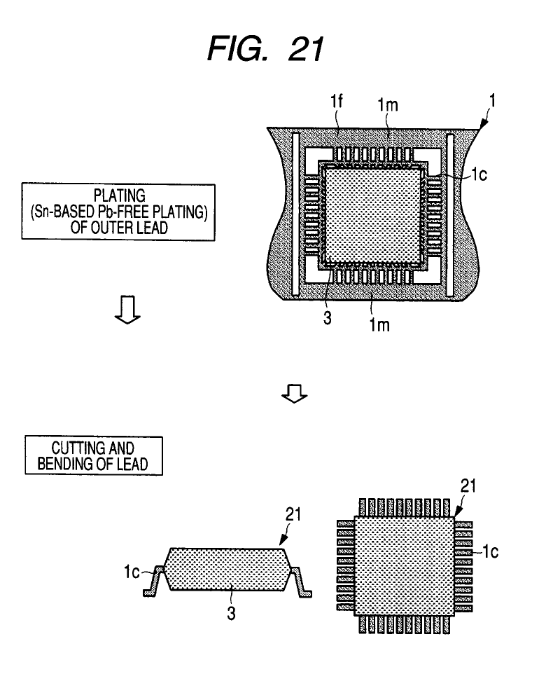

FIG. 15 is a cross-sectional view illustrating the structure of a QFP as one example of a semiconductor device according to Embodiment 2 of the present invention; FIG. 16 includes a cross-sectional view and partial plan view illustrating one example of the formation of a Pd plated layer in the preparation of a lead frame to be used for the fabrication of the QFP illustrated in FIG. 15; FIG. 17 includes a partial plan view illustrating one example of a masked back surface of the frame prior to the formation of a Pd-plated layer in the preparation of the lead frame shown in FIG. 16; FIG. 18 is a partial plan view illustrating one example of the plated back surface of the frame after formation of a Pd plated layer in the preparation of the lead frame shown in FIG. 16; FIG. 19 includes a plan view and partial plan view illustrating one example of the steps until the completion of die bonding in the fabrication of the QFP shown in FIG. 15; FIG. 20 is a partial plan view illustrating one example of the steps from wire bonding to the completion of resin molding in the fabrication of the QFP shown in FIG. 15; and FIG. 21 includes a plan view, partial plan view and side surface view illustrating one example of the steps from the formation of a plated layer on the outer lead until the completion of cutting and bending of the lead in the fabrication of the QFP shown in FIG. 15.

The semiconductor device of Embodiment 2 illustrated in FIG. 15 is a QFP 21 similar to that of Embodiment 1. Difference of it from the QFP 6 of Embodiment 1 resides in that a lead (Pb)-free plated layer to be formed on the surface of the outer lead 1c is changed from the palladium (Pd) plated layer 1a to a tin (Sn)-based lead-free plated layer 1m. The tin-based lead-free plated layer 1m is formed only on the portion of the outer lead 1c exposed from the resin sealant and is not formed at all in the resin sealant 3, because in the QFP 21, the tin-based lead-free plated layer 1m is formed on the outer lead 1c after the formation of the resin sealant 3. The other structure of the QFP 21 is exactly the same as that of the QFP 6 of Embodiment 1 so that overlapping description will be omitted.

The tin-based lead-free plated layer 1m is made of, for example, a pure tin metal, a tin-bismuth (Sn—Bi)-based metal or tin-silver-copper (Sn—Ag—Cu)-based metal.

The QFP 21 of Embodiment 2 also intends to eliminate a lead (Pb) content from plating. The tin-based lead-free plated layer 1m is formed on the surface of each of the outer leads 1c as external plating, while the palladium plated layer 1a is formed on the wire bonding portion 1j near the chip side end portion of each of the inner leads 1b.

Moreover, similar to the QFP 6 of Embodiment 1, the plated layer (copper plated layer) 1g is formed, in a region other than a portion of the inner lead 1b in which the palladium plated layer la has been formed, by strike plating to expose the pure copper (Cu) layer 1h.

Similar effects to those available by the QFP 6 of Embodiment 1 can therefore be obtained. Described specifically, in a region where the plated layer 1g of each of the inner leads 1b is exposed, the oxide film 1u acquires high density and becomes a strong Cu₂O layer as illustrated in FIG. 13, thereby making it possible to improve the adhesion with the resin of the resin sealant 3. The plated layer 1g formed by strike plating is bonded to the resin 3, whereby the adhesion between the sealing resin and inner lead 1b can be improved, resulting in the improvement of the reliability of the QFP 21.

The tin-based lead free plating employed as the lead-free plating is lower in the material cost than palladium plating and it contributes to a reduction in the manufacturing cost of the semiconductor device. In particular, when a pure tin (Sn) metal is employed, the manufacturing cost can be reduced more compared with the use of a tin-based alloy.

The fabrication of the QFP 21 according to Embodiment 2 will next be described.

The fabrication of the QFP 21 is substantially similar to that of the QFP 6 of Embodiment 1. Two plating steps, that is, palladium plating and tin-based lead-free plating are however necessary for plating of the lead frame 1. Formation of a plated layer by strike plating is therefore followed by another plating step.

In the QFP 6 of Embodiment 1, the palladium plated layers 1a are formed over the wire bonding portion 1j of the inner lead 1b and the outer lead 1c, respectively and they are formed in one plating step. In the QFP 21 of Embodiment 2, on the other hand, the palladium plated layer 1a is formed on the wire bonding portion 1j of the inner lead 1b and the tin-based lead-free plated layer 1m is formed over the outer lead 1c so that they are formed by respective plating steps.

A difference from Embodiment 1 will next be described. First, in the preparation of the lead frame 1, a plated layer 1g having pure copper is formed on the lead frame 1 by strike plating in a similar manner to that shown in FIGS. 2 to 4 of Embodiment 1.

The palladium plated layer 1a is then formed only on the wire bonding portion 1j of the inner lead 1b shown in FIG. 16. First, a nickel (Ni) plated layer to be located below the palladium plated layer 1a is formed. A mask 1x is attached to a predetermined position as shown in “Before plating” of FIG. 16. This mask 1x is attached so as to expose only the wire bonding portion 1j of the inner lead 1b in order to form a palladium plated layer on the wire bonding portion 1j of the inner lead 1b.

On the back surface side of the frame, a mask 1x is attached so as to cover the entire surface of the lead therewith as illustrated in FIG. 17. The resulting lead frame 1 is then dipped in a nickel plating bath to form a nickel plated layer over the wire bonding portion 1j of the inner lead 1b.

By dipping the lead frame 1 in a palladium plating solution 13a in a palladium plating tank 13, the palladium plated layer 1a is formed over the nickel plated layer. In short, the palladium plated layer 1a is formed over the wire bonding portion 1j of the inner lead 1b as illustrated in “After plating” of FIG. 16. As illustrated in FIG. 18, no palladium plated layer 1a is formed on the back surface side of the frame.

The lead frame 1 thus obtained is then washed to complete the plating steps.

By these steps, the lead frame 1 having, at the wire bonding portion 1j of the inner lead 1b thereof, the palladium plated layer 1a and having the pure copper plated layer 1g exposed from the other region is obtained as illustrated in “After plating” of FIG. 16 and FIG. 18.

In a region of the inner lead 1b of the lead frame 1 other than the wire bonding portion 1j, the pure copper plated layer 1g is exposed and owing to presence of a sufficient amount of copper, a natural oxide film of Cu₂O is formed on this plated layer 1g.

Fabrication of the QFP 21 by using the lead frame 1 which has finished the plating steps will next be described.

As illustrated in “Preparation of lead frame” of FIG. 19, a lead frame 1 equipped with a tab 1q having a supporting surface 1p whose outside dimension is smaller than that of the back surface 2c of the semiconductor chip 2 (refer to FIG. 15) to be mounted on the tab and a plurality of inner leads 1b and outer leads 1c arranged to extend around the tab 1q; and is made using a copper alloy as a raw material is prepared.

On the wire bonding portion 1j of the inner lead 1b of the lead frame 1, the palladium plated layer 1a is formed, while the pure copper plated layer 1g is formed in a region other than the wire bonding portion 1j by strike plating so as to expose it.

Die bonding as illustrated in FIG. 19 is thereafter carried out. Described specifically, the semiconductor chip 2 is mounted on the supporting surface 1p of the tab 1q. At the time of mounting, as illustrated in FIG. 10 of Embodiment 1, the tab 1q is disposed on a die bonding stage 7, a die bonding material 8 is applied onto the supporting surface 1p of the tab 1q, and then the semiconductor chip 2 is mounted thereon, whereby the semiconductor chip 2 is mounted on the supporting surface 1p of the tab 1q via the die bonding material 8.

Wire bonding as illustrated in FIG. 20 is then performed. As illustrated in FIG. 10, a pad (surface electrode) 2a of the semiconductor chip 2 and inner lead 1b are electrically connected via a conductive wire 4 by the aid of a capillary 14 while bringing the semiconductor chip 2 and inner lead 1b into contact with the upper surface of the heat stage 19 and heating them. On the side of the inner lead 1b, the wire 4 is connected to the palladium plated layer 1a formed on the wire bonding portion 1j of the inner lead 1b.

In the wire bonding step, the inner lead 1b is bonded to the wire by bringing it into contact with the heat stage 19 so that the inner lead 1b becomes hot by heating. As a result of heating, the oxide film 1u (first oxide film) naturally formed by oxidation on the plated layer 1g having pure copper becomes a stronger film (second oxide film) and this strong oxide film (second oxide film) increases as in Embodiment 1.

The wire bonding is followed by resin molding as illustrated in FIG. 20. The resin molding is performed by filling a resin (sealing resin) 17 in a cavity 18c from an inlet 18d while clamping the lead frame 1 with a top force 18a and a bottom force 18b of a molding die 18. The tab 1q, inner leads 1b, semiconductor chip 2 and a plurality of wires 4 are sealed with the resin, resulting in the formation of a resin sealant 3 as illustrated in “Resin molding” of FIG. 20.

After completion of the resin molding, a tin-based lead-free plated layer 1m is formed on the outer lead 1c protruding from the resin sealant 3. Described specifically, while maintaining the connection between the frame portion 1f and outer lead 1c, the tin-based lead-free plated layer 1m is formed on the outer lead 1c and frame portion 1f.

The tin-based lead-free plated layer 1m may be formed on the outer lead 1c in advance at preparation of the lead frame 1. Heat during wire bonding may melt the tin-based lead-free plated layer 1m and cause wire bonding failure so that it is preferred to form the tin-based lead-free plated layer 1m on the outer lead 1c after the resin molding step. When tin-based lead-free plating has a very high melting point and does not melt even by wire bonding, the tin-based lead-free plated layer 1m may be formed on the outer lead 1c in advance at the stage of the lead frame 1.

After completion of the formation of the plated layer on the outer lead 1c, cutting and bending of the outer lead 1c are carried out as shown in “Cutting and bending of lead” of FIG. 21. Described specifically, each of the outer leads 1c is separated from the frame portion 1f of the lead frame 1 of FIG. 19 by cutting of the lead and then each outer lead 1c is bent in a gull-wing shape. The fabrication of the QFP 21 is thus completed.

### EMBODIMENT 3

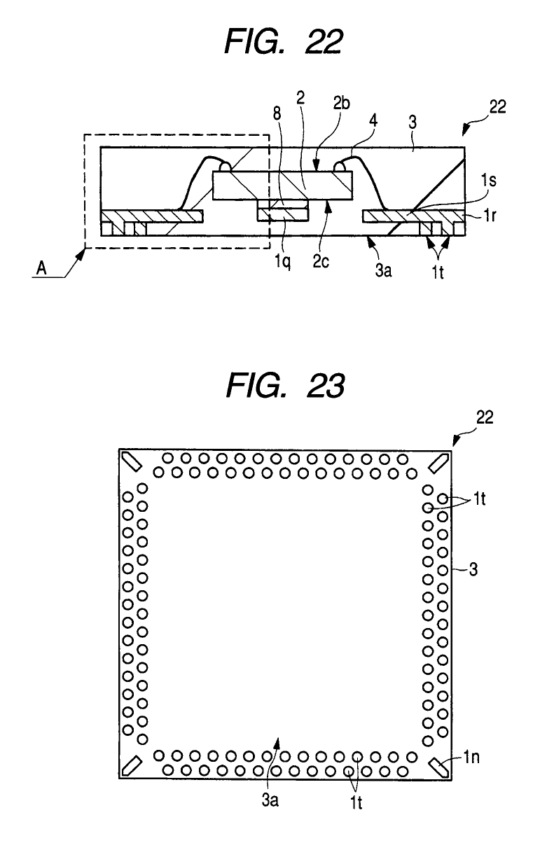

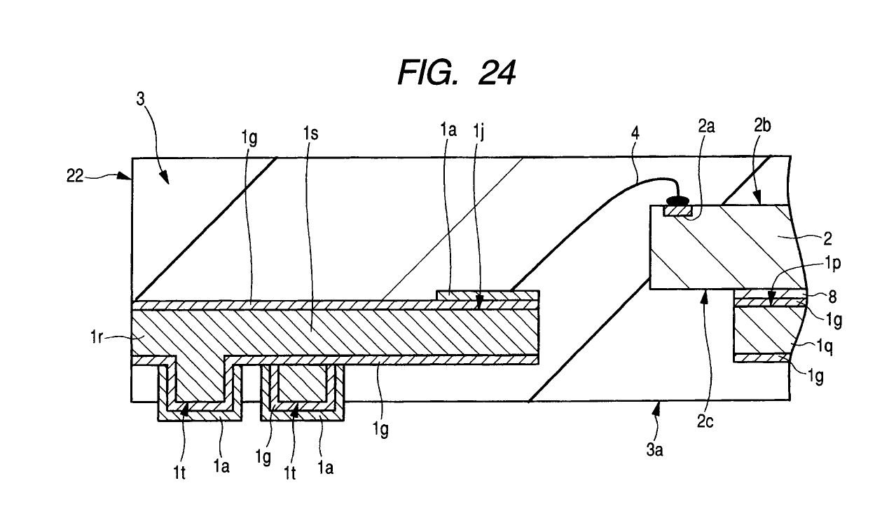

FIG. 22 is a cross-sectional view illustrating the structure of QFN which is one example of a semiconductor device according to Embodiment 3 of the present invention; FIG. 23 is a back side view illustrating the structure of the back surface of the QFN illustrated in FIG. 22; and FIG. 24 is a partially enlarged cross-sectional view illustrating the enlarged structure of Portion A illustrated in FIG. 22.

The semiconductor device according to Embodiment 3 is, similar to that of Embodiment 1, a resin sealed type obtained by resin molding and at the same time, a surface mount type. In Embodiment 3, as one example of this semiconductor device, a QFN (Quad Flat Non-leaded package) 22 illustrated in FIG. 22 will be taken up for description.

The constitution of the QFN 22 illustrated in FIGS. 22 to 24 will hereinafter be described. It comprises a semiconductor chip 2 having a main surface 2b and a back surface 2c opposite to the main surface 2b and having a semiconductor integrated circuit mounted on the chip, a tab 1q having a supporting surface 1p which is to be bonded to the back surface 2c of the semiconductor chip 2 and has an outside dimension smaller than that of the back surface 2c of the semiconductor chip 2, and a plurality of conductive wires 4 electrically connected to a plurality of pads 2a of the semiconductor chip 2. Further, it has a plurality of leads 1r which extend around the semiconductor chip and have, at a wire bonding portion 1j thereof to which the wire 4 is bonded, a palladium (Pd) plated layer 1a, and a resin sealant 3 for sealing the semiconductor chip 2 and the plurality of wires 4 with a resin.

Each of the leads 1r has an inner portion (first portion) 1s disposed inside the resin sealant 3 and to be bonded to the sealing resin; and an outer portion (second portion) 1t exposed from the back surface (mounting surface) 3a of the resin sealant 3. The leads 1r and the tab 1q are each made of a thin plate material formed using a copper (Cu) alloy as a raw material.

The outer portions 1t have a function as an external connection terminal and are arranged in two rows alternately along the circumferential portion of the back surface 3a of the resin sealant 3, so-called in a zigzag manner as illustrated in FIG. 23. As illustrated in FIG. 24, the palladium plated layer 1a has been formed over the wire bonding portion 1j of the inner portion 1s and the outer portion 1t. Described specifically, the inner portion 1s has a main surface and a back surface opposite to each other, and two side surfaces located between the main surface and the back surface. The palladium plated layer 1a on the inner portion 1s is formed only on the end portion of the main surface of the inner portion 1s and at the same time opposite to the semiconductor chip 2.

Also in the QFN 22, similar to the QFP 6 of Embodiment 1, a plated layer (copper plated layer) 1g having a pure copper layer 1h on the surface thereof as illustrated in FIG. 12 is formed by strike plating so as to expose it from a region other than a portion of the each of the leads 1r on which the palladium plated layer 1a has been formed. Accordingly, the copper plated layer 1g is bonded to the resin sealant 3 inside the resin sealant 3 as shown in FIG. 24.

The semiconductor chip 2 is made of, for example, silicon and is firmly fixed to the supporting surface 1p of the tab 1q via a die bonding material 8.

The wire 4 is for example a gold (Au) wire. The sealing resin which constitutes the resin sealant 3 is, for example, a thermosetting epoxy resin.

Since the external connection terminals are arranged in two rows along one side of the resin sealant 3 in the QFN 22 of Embodiment 3, at least an end portion of the inner portion is must be extended to a position of the external connection terminal arranged closer to the semiconductor chip 2. It is performed because, in the wire bonding step, the wires connected to the side of the lead 1r must be arranged in one row along one side of the resin sealant 3. In the case of the QFN type semiconductor device as shown in Embodiment 3 having a long inner portion 1s, such a structure increases a contact area between the resin and lead 1r. It is therefore necessary to improve the adhesion between the resin and lead frame.

The QFN 22 of Embodiment 3 therefore intends to actualize lead (Pb)-free plating similar to the QFP 6 of Embodiment 1. A palladium plated layer 1a, one example of a lead-free plated layer as external plating is formed on the surface of the outer portion of each of the leads 1r exposed outside. Moreover, the palladium plated layer 1a is also formed on the wire bonding portion 1j, on the side of the chip, of the inner portion is of each of the leads 1r disposed inside the resin sealant 3.

Similar to the QFP 6 of Embodiment 1, the plated layer 1g having, on the surface thereof, the pure copper layer 1h (refer to FIG. 12) is formed and exposed in region other than a portion of each of the leads 1r on which the palladium plated layer 1a has been formed.

Similar effects to those brought by the QFP 6 of Embodiment 1 are therefore available. Described specifically, in a region from which the plated layer 1g of each of the leads 1r is exposed, the oxide film 1u illustrated in FIG. 13 acquires high density and becomes a CuO₂ layer which is a strong film, thereby improving the adhesion with the resin of the resin sealant 3. The plated layer 1g formed by strike plating is bonded to the resin sealant 3 so that adhesion between the sealing resin and inner lead 1b can be improved and as a result, the QFN 22 can have improved reliability.

In a semiconductor device having a QFN structure, the lead 1r is apt to drop off from the resin sealant 3 because a contact area between the lead 1r and resin sealant 3 (sealing resin) is smaller than that in the QFP 6 and at the same time, the lead 1r is not enclosed in the sealing resin completely. In the QFN 22 according to Embodiment 3, on the other hand, the plated layer 1g having on the surface thereof the pure copper layer 1h has been formed by strike plating so as to be exposed from a region other than a portion of each of the leads 1r on which the palladium plated layer 1a has been formed. It is therefore possible to improve the adhesion between the lead 1r and resin sealant 3 (sealing resin), thereby reducing the dropout of the lead 1r from the resin sealant 3.

The Pb-free plated layer formed on the outer portion 1t of the lead 1r of the QFN 22 is not limited to a palladium plated layer and it may be a tin (Sn) based lead (Pb)-free plated layer composed of a pure tin (Sn) metal, tin-bismuth (Sn—Bi) based metal, tin-silver-copper (Sn—Ag—Cu) based metal or the like as described in Embodiment 2.

The invention made by the present inventors was described specifically based on some embodiments of the present invention. It is needless to say that the invention is not limited to or by them, but various modifications or changes can be made without departing from the scope of the invention.

For example, in Embodiment 3, the QFN 22 in which outer portions 1t of the leads 1r have been arranged in two rows in a zigzag manner at the circumferential portion of the back surface 3a of the resin sealant 3 was explained. The leads 1r are not necessarily arranged in two rows and they may be arranged in one row at the circumferential portion.

In addition, use of a lead-free replacement for tin-lead (Sn—Pb) eutectic solder for overcoming environmental pollution problems was explained, but use of it is not limited to the above-described purpose. When treatment is performed in a thermal atmosphere of 200° C. or greater, use of the present invention can improve the adhesion between a resin and a lead frame so that peeling which will otherwise occur at the interface between the resin and the lead frame can be suppressed.

In Embodiments 1 and 2, a semiconductor device having the outer lead 1c protruding from the four sides of the rectangular resin sealant 3, that is, so-called QFP was explained. The present invention is effective when applied not only to it but also to a semiconductor device equipped with the outer lead 1c protruding from two sides of the resin sealant 3 opposite to each other, that is, so-called SOP (Small Outline Package) type semiconductor device. The present invention is however more effective when applied to the QFP type semiconductor device because the number of the inner leads 1b sealed with the resin sealant 3 is greater in the QFP type semiconductor device than in the SOP type semiconductor device.

The present invention is suited for lead elimination from electronic devices.

1. A semiconductor device comprising:
a chip mounting portion;
a plurality of leads arranged around the chip mounting portion;
a semiconductor chip mounted over the chip mounting portion;
a plurality of wires for electrically coupling a plurality of surface electrodes of the semiconductor chip to wire bonding portions of first portions of the leads, respectively; and
a resin sealant for sealing the semiconductor chip, the first portions and the wires,
wherein a pure copper layer is formed over the surface of the leads,
wherein a palladium plated layer is formed over the uppermost surface of the wire bonding portions,
wherein the wires are electrically coupled to the wire bonding portions via the palladium plated layer, and
wherein a portion of the resin sealant is bonded to the pure copper layer.

2. A semiconductor device according to claim 1, wherein the chip mounting portion has a chip supporting surface having an outside dimension smaller than that of the back surface of the semiconductor chip.

3. A semiconductor device according to claim 2, wherein the pure copper layer is formed between the chip supporting surface and the back surface of the semiconductor chip, and the semiconductor chip is mounted over the chip mounting portion via a die bonding material.

4. A semiconductor device according to claim 1, wherein each of the leads has a second portion connected integrally to the first portion and at the same time exposed from the resin sealant, and a palladium plated layer is formed over the uppermost surface of the second portion.

5. A semiconductor device according to claim 1, wherein the first portion has: a main surface and a back surface opposite to each other; and a side surface located between the main surface and the back surface, and the wire bonding portion is an end portion located over the main surface of the first portion and opposite to the semiconductor chip.

6. A semiconductor device according to claim 1, wherein the palladium plated layer over the wire bonding portion and the second portion has a nickel layer below the palladium layer.

7. A semiconductor device according to claim 1, wherein the palladium plated layer over the wire bonding portion and the second portion have a gold layer above the palladium layer.

8. A semiconductor device according to claim 1, wherein a portion of the palladium plated layer formed over the second portion extends over the first portion and at the same time is covered with the resin sealant.

9. A semiconductor device according to claim 1, wherein the pure copper layer is a multilayer made of a copper based metal and containing no impurity except copper.

10. A semiconductor device comprising:
a semiconductor chip having a main surface and a back surface opposite thereto;
a tab having a supporting surface which is to be bonded to the back surface of the semiconductor chip and has an outside dimension smaller than that of the back surface of the semiconductor chip;
a conductive wire to be coupled to a surface electrode of the semiconductor chip;
a plurality of inner leads which extend around the semiconductor chip, have a palladium plated layer formed over a wire bonding portion to which the wire is to be bonded and are formed using a copper alloy as a raw material;
a resin sealant for sealing, with a resin, the semiconductor chip, the wire and the inner leads; and
a plurality of outer leads exposed from the side portion of the resin sealant while being connected integrally to the inner leads and having a palladium plated layer formed over the surface,
wherein inside the resin sealant, a strike plated layer having, over the surface thereof, a pure copper layer is formed to exposed it in a region of each of the inner leads other than the wire bonding portion and is bonded to the resin sealant.

11. A semiconductor device according to claim 10, wherein the palladium plated layers over the wire bonding portion and outer leads have each a nickel layer below the palladium layer.

12. A semiconductor device according to claim 10, wherein the palladium plated layers over the wire bonding portion and outer leads have each a gold layer above the palladium layer.

13. A semiconductor device according to claim 10, wherein a portion of the palladium plated layer formed over the surface of the outer lead extends over the inner lead and at the same time, is covered with the resin sealant.

14. A semiconductor device according to claim 10, wherein the strike plated layer is a multilayer made of a copper based metal and has, as the uppermost layer thereof, the pure copper layer.

15. A semiconductor device comprising:
a semiconductor chip having a main surface and a back surface opposite thereto;
a tab having a supporting surface which is to be bonded to the back surface of the semiconductor chip and has an outside dimension smaller than that of the back surface of the semiconductor chip;
a conductive wire to be coupled to a surface electrode of the semiconductor chip;
a resin sealant for sealing, with a resin, the semiconductor chip and the wire; and
a plurality of leads which extend around the semiconductor chip, have each a first portion having, over a wire bonding portion thereof to which the wire is bonded, a palladium plated layer and being disposed inside the resin sealant and a second portion exposed from the resin sealant and having a tin-based lead-free plated layer formed thereover, and are made using a copper alloy as a raw material,
wherein inside the resin sealant, a strike plated layer having a pure copper layer over the surface thereof is formed to expose it in a region of the first portion of each of the leads other than the wire bonding portion and is bonded to the resin sealant.

16. A semiconductor device according to claim 15, wherein the tin-based lead free plated layer is made of any one of a pure tin metal, tin-bismuth based metal and tin-silver-copper based metal.

17. A semiconductor device according to claim 15, wherein a portion of the tin-based lead-free plated layer formed over the second portion extends over the first portion and at the same time, is covered with the resin sealant.

18. A semiconductor device according to claim 15, wherein the strike plated layer is a multilayer made of a copper-based metal and has, as the uppermost layer thereof, the pure copper layer.

19. A semiconductor device comprising:
a semiconductor chip having a main surface and a back surface opposite thereto;
a tab having a supporting surface which is to be bonded to the back surface of the semiconductor chip and has an outside dimension smaller than that of the back surface of the semiconductor chip;
a conductive wire to be coupled to a surface electrode of the semiconductor chip;
a plurality of inner leads which extend around the semiconductor chip, have a palladium plated layer over the wire bonding portion to which the wire is to be bonded and are made using a copper alloy as a raw material;
a resin sealant for sealing, with a resin, the semiconductor chip, the wire, and the inner leads; and
a plurality of outer leads which are formed integrally with the inner leads, are exposed from the side portion of the resin sealant and have a tin-based lead-free plated layer formed over the surface,
wherein inside the resin sealant, a strike plated layer having a pure copper layer over the surface thereof is formed to expose it from a region of each of the inner leads other than the wire bonding portion and is bonded to the resin sealant.

20. A semiconductor device according to claim 19, wherein the tin-based lead free plated layer is made of any one of pure tin metal, tin-bismuth based metal and tin-silver-copper based metal.

21. A semiconductor device according to claim 15, wherein a portion of the tin-based lead-free plated layer formed over each of the outer leads extends over each of the inner leads and at the same time, is covered with the resin sealant.

22. A semiconductor device according to claim 19, wherein the strike plated layer is a multilayer made of a copper-based metal and has, as the uppermost layer thereof, a pure copper layer.

23. A manufacturing method of a semiconductor device, comprising the steps of:
(a) preparing a lead frame having a tab whose supporting surface has an outside dimension smaller than that of the back surface of a semiconductor chip to be mounted over the tab and a plurality of leads arranged to extend around the tab, and being formed using a copper alloy as a raw material;
(b) mounting the semiconductor chip over the supporting surface of the tab;
(c) electrically coupling a surface electrode of the semiconductor chip to a palladium plated layer formed over a wire bonding portion of each of the leads via a conductive wire; and
(d) sealing, with a resin, the tab, the semiconductor chip and the wire of the lead frame in which a palladium plated layer has been formed over a portion of each of the leads and the wire bonding portion and a strike plated layer having over the surface thereof a pure copper layer has been formed to expose it from a region other than the portion of each of the leads and the wire bonding portion,
wherein a first region of each of the leads from which the strike plated layer is exposed is bonded to the resin sealant inside the resin sealant, and
wherein a second region exposed from the resin sealant has, over the surface thereof, a palladium plated layer.

24. A manufacturing method of a semiconductor device according to claim 23, comprising, prior to the step (c), a step of forming the strike plated layer and the palladium plated layer of the wire bonding portion.

25. A manufacturing method of a semiconductor device according to claim 23, wherein in the step (a), the lead frame in which the palladium plated layer has been formed over the portion of each of the leads and the wire bonding portion and at the same time, the strike plated layer has been formed to expose it in a region other than the portion of each of the leads and the wire bonding portion in advance.

26. A manufacturing method of a semiconductor device, comprising the steps of:
(a) preparing a lead frame having a tab whose supporting surface has an outside dimension smaller than that of the back surface of a semiconductor chip to be mounted over the tab and a plurality of leads arranged to extend around the tab and being made using pure copper as a raw material;
(b) mounting the semiconductor chip over the supporting surface of the tab;
(c) electrically coupling a surface electrode of the semiconductor chip to a palladium plated layer formed over a wire bonding portion of each of the leads via a conductive wire;
(d) sealing, with a resin, the tab, the semiconductor chip and the wire of the lead frame in which a palladium plated layer has been formed over the leads and the wire bonding portion and a strike plated layer having over the surface thereof a pure copper layer has been formed to expose it from a region other than wire bonding portion; and
(e) forming a tin-based lead-free plated layer in a second region of each of the leads which is exposed from the resin sealant,
wherein a first region of each of the leads from which the strike plated layer is exposed is bonded to the resin sealant inside the resin sealant, and
wherein the second region exposed from the resin sealant has, over the surface thereof, a tin-based lead-free plated layer.

27. A manufacturing method of a semiconductor device according to claim 26, comprising, prior to the step (c), a step of forming the strike plated layer and the palladium plated layer of the wire bonding portion.

28. A manufacturing method of a semiconductor device according to claim 26, wherein in the step (a), the lead frame in which the palladium plated layer has been formed over the wire bonding portion of each of the leads and at the same time, the strike plated layer has been formed to expose it in a region other than the wire bonding portion in advance.
